(19) United States
(12) Patent Application Publication
(10) Pub. No.: US 2024/0164163 A1
(43) Pub. Date: May 16, 2024

(54) DISPLAY DEVICE AND METHOD FOR MANUFACTURING THE SAME

(71) Applicant: Samsung Display Co., LTD., Yongin-si (KR)

(72) Inventors: DAEIL KIM, Yongin-si (KR); SOODONG SON, Yongin-si (KR); DONG-YOON SO, Yongin-si (KR); YONGCHUL KIM, Yongin-si (KR)

(21) Appl. No.: 18/467,527

(22) Filed: Sep. 14, 2023

(30) Foreign Application Priority Data
Nov. 15, 2022 (KR) 10-2022-0152979

(51) Int. Cl. H10K 59/131; H10K 59/12; H10K 59/124

(52) U.S. Cl. CPC H10K 59/131; H10K 59/1201; H10K 59/124; H10K 59/40

(57) ABSTRACT

A display device includes a substrate including display and pad areas, a transistor including an active pattern, a gate electrode above the active pattern, and source and drain electrodes, a connection electrode above the transistor, and coupled to the transistor, a touch layer above the connection electrode, and including an upper touch electrode, pads including a first pad electrode including a same material as the gate electrode, a second pad electrode above the first pad electrode, and including a same material as the source and drain electrodes, a third pad electrode above the second pad electrode, and including a same material as the connection electrode, and a fourth pad electrode above the third pad electrode, and including a same material as the upper touch electrode, and an additional insulating layer, covering an edge of the third pad electrode, and having an upper surface directly contacting the fourth pad electrode.

### CROSS-REFERENCE TO RELATED APPLICATION

This application claims priority to, and the benefit of, Korean Patent Application No. 10-2022-0152979, filed on Nov. 15, 2022, in the Korean Intellectual Property Office (KIPO), the entire contents of which are hereby incorporated by reference.

### BACKGROUND

### 1. Field

Embodiments relate to a display device that provides visual information, and a method for manufacturing the display device.

### 2. Description of the Related Art

With the development of information technology, the importance of a display device, which is a connection medium between a user and information, has been highlighted. For example, the use of a display device, such as a liquid crystal display device (“LCD”), an organic light-emitting display device (“OLED”), a plasma display device (“PDP”), a quantum dot display device, and the like is increasing.

### SUMMARY

A display device according to embodiments of the present disclosure includes a substrate including a display area, and a pad area adjacent to the display area, a transistor including an active pattern in the display area above the substrate, a gate electrode above the active pattern, and a source electrode and a drain electrode coupled to the active pattern, a connection electrode above the transistor, and coupled to the transistor, a touch layer above the connection electrode, and including an upper touch electrode, pads above the substrate in the pad area, and including a first pad electrode including a same material as the gate electrode, a second pad electrode above the first pad electrode, and including a same material as the source electrode and the drain electrode, a third pad electrode above the second pad electrode, and including a same material as the connection electrode, and a fourth pad electrode above the third pad electrode, and including a same material as the upper touch electrode, and an additional insulating layer above the substrate in the pad area, covering an edge of the third pad electrode, and having an upper surface directly contacting the fourth pad electrode.

An entirety of a lower surface of the fourth pad electrode may directly contact the additional insulating layer or the third pad electrode.

The display device may further include a first insulating layer above the active pattern, and covering the gate electrode and an edge of the first pad electrode, and a second insulating layer above the first insulating layer, and covering an edge of the first insulating layer, wherein the first and second insulating layers expose a central portion of the first pad electrode in the pad area.

The second pad electrode may directly contact the central portion of the first pad electrode.

Openings may be respectively defined in the additional insulating layer between adjacent ones of the pads, and may expose an upper surface of the second insulating layer.

The pads may be repeatedly arranged along a first direction and a second direction, which crosses the first direction, wherein first openings among the openings are respectively positioned between ones of the pads arranged along the first direction, and extend in the second direction.

Second openings of the openings may be respectively positioned between ones of the pads respectively arranged in a first row and in a second row, which is adjacent to the first row, and may extend in the first direction.

The additional insulating layer may include an organic material.

The display device may further include a first organic insulating layer covering the source electrode and the drain electrode, and a second organic insulating layer above the first organic insulating layer, and covering the connection electrode, wherein the additional insulating layer includes a same material as the second organic insulating layer.

The touch layer may further include a touch insulating layer between the connection electrode and the upper touch electrode.

The pad area may include a first area and a second area in which the pads are located, wherein the touch insulating layer is omitted from the first area or the second area.

The first area or the second area may include sub-areas spaced apart from each other along a first direction, and extending in a second direction crossing the first direction, wherein the touch insulating layer is omitted from the sub-areas.

The touch insulating layer may cover a side surface of the additional insulating layer, and may be omitted from between the third pad electrode and the fourth pad electrode.

The touch insulating layer may be separated from the third pad electrode.

The third pad electrode may include a first conductive layer, a second conductive layer, and a third conductive layer sequentially stacked, the first and third conductive layers protruding more than the second conductive layer in a direction toward the additional insulating layer.

The third pad electrode may directly contact the second pad electrode, wherein the fourth pad electrode directly contacts the third pad electrode.

A method for manufacturing a display device according to embodiments of the present disclosure includes forming an active pattern in a display area above a substrate including the display area and a pad area, which is adjacent to the display area, concurrently forming a gate electrode in the display area above the active pattern, and a first pad electrode in the pad area above the substrate, concurrently forming a source electrode and a drain electrode coupled to the active pattern, and a second pad electrode above the first pad electrode, concurrently forming a connection electrode coupled to the drain electrode, and a third pad electrode above the second pad electrode, forming an additional insulating layer covering an edge of the third pad electrode, forming a touch insulating layer above the connection electrode, the additional insulating layer, and the third pad electrode, exposing a portion of an upper surface of the third pad electrode by removing a portion of the touch insulating layer in an area in which the first pad electrode, the second pad electrode, and the third pad electrode are positioned in the pad area, and concurrently forming an upper touch electrode above the touch insulating layer, and a fourth pad electrode above the third pad electrode.

The additional insulating layer may cover the edge of the third pad electrode, and may have an upper surface directly contacting the fourth pad electrode.

An entirety of a lower surface of the fourth pad electrode may directly contact the additional insulating layer or the third pad electrode.

The touch insulating layer may cover a side surface of the additional insulating layer, may be omitted from between the third pad electrode and the fourth pad electrode, and may be separated from the third pad electrode.

In a display device according to one or more embodiments of the present disclosure, a plurality of pads each including first, second, third, and fourth pad electrodes sequentially stacked, and an insulating layer covering the third pad electrode and including an organic material, may be located in a pad area. The insulating layer may directly contact the fourth pad electrode. In addition, an entire lower surface of the fourth pad electrode may directly contact the third pad electrode and the insulating layer. That is, the touch insulating layer might not be located between the third pad electrode and the fourth pad electrode. Accordingly, after the reliability evaluation of the display device is performed in a high-temperature and high-humidity environment, lifting of a driving integrated circuit may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a view illustrating a bent shape of the display device of FIG. 1.

FIG. 3 is a block view illustrating an external device electrically connected to the display device of FIG. 1.

FIGS. 4 and 5 are enlarged plan views of an example of area A of FIG. 1.

FIG. 6 is a cross-sectional view illustrating an example in which an integrated circuit is located on a plurality of pads of FIG. 5.

FIG. 7 is a cross-sectional view taken along the line I-I′ of FIG. 1 and the line II-II′ of FIG. 4.

FIG. 8 is an enlarged cross-sectional view of area B of FIG. 7.

FIG. 9 is an enlarged plan view of a portion of a second area of FIG. 4.

FIG. 10 is a cross-sectional view taken along the line III-III′ of FIG. 9.

FIGS. 11, 12, 13, 14, 15, 16, 17, 18, and 19 are cross-sectional views illustrating a method for manufacturing the display device of FIG. 7.

FIGS. 20 and 21 are enlarged plan views of other examples of area A of FIG. 1.

FIG. 22 is an enlarged plan view of another example of area A of FIG. 1.

FIG. 23 is a cross-sectional view taken along the line I-I′ of FIG. 1 and the line IV-IV′ of FIG. 22.

FIG. 24 is an enlarged plan view of another example of area A of FIG. 1.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

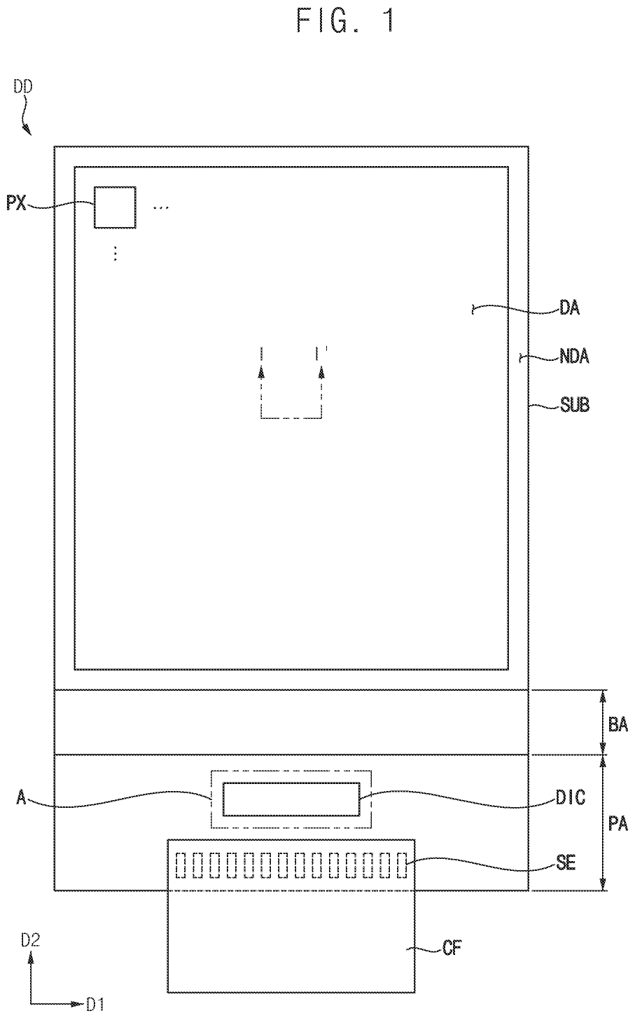

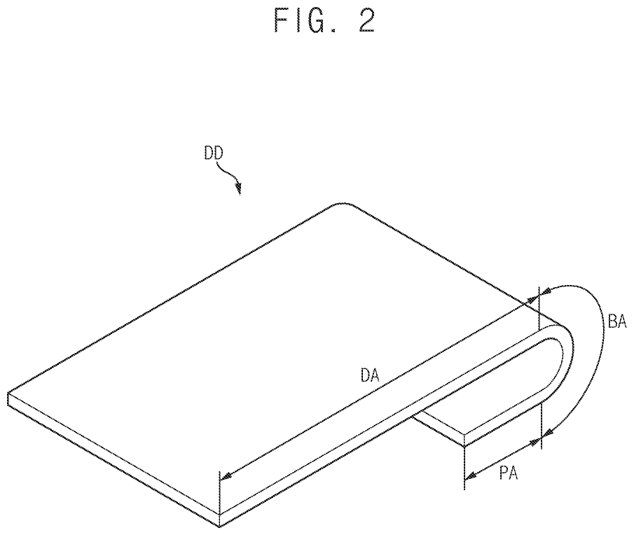

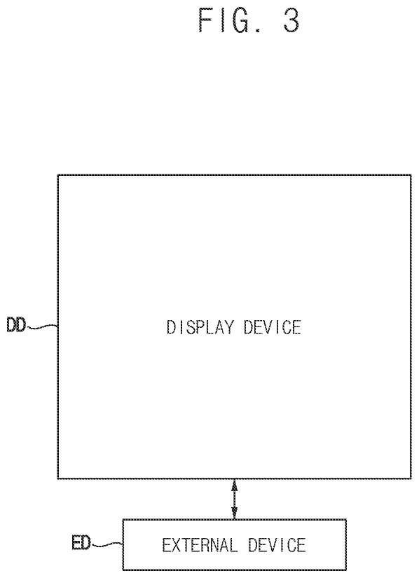

FIG. 1 is a plan view illustrating a display device according to one or more embodiments of the present disclosure. FIG. 2 is a view illustrating a bent shape of the display device of FIG. 1. FIG. 3 is a block view illustrating an external device electrically connected to the display device of FIG. 1.

Referring to FIGS. 1, 2, and 3, a display device DD according to one or more embodiments may include a substrate SUB, a driving integrated circuit DIC, signal pads SE, and a connection film CF.

The display device DD may have a rectangular planar shape. However, the present disclosure is not limited thereto, and the display device DD may have various planar shapes.

The substrate SUB may include a display area DA and a non-display area NDA. The display area DA may be defined as an area capable of displaying an image by generating light, or by adjusting transmittance of light provided from an external light source. The non-display area NDA may be defined as an area not displaying an image. In addition, the non-display area NDA may surround at least a portion of the display area DA (e.g., in plan view). For example, the non-display area NDA may entirely surround the display area DA.

The non-display area NDA may include a bending area BA and a pad area PA. The pad area PA may be spaced apart from one side of the display area DA in a direction opposite to a second direction DR2 and parallel to an upper surface of the substrate SUB.

The bending area BA may be positioned between the display area DA and the pad area PA in a plan view. As illustrated in FIG. 2, the bending area BA may be bent based on a bending axis extending in a first direction DR1. In this case, the display area DA and the pad area PA may overlap in the plan view. The display device DD may be provided in a shape in which the bending area BA is bent based at the bending axis.

A plurality of pixels PX may be located in the display area DA. Each of the plurality of pixels PX may emit light. As each of the plurality of pixels PX emits light, the display area DA may display an image. For example, the plurality of pixels PX may be arranged in a matrix form along the first direction DR1 and the second direction DR2, which crosses the first direction DR1.

Lines connected to the plurality of pixels PX may be further located in the display area DA. For example, the lines may include a data signal line, a gate signal line, and a power line.

A driver for driving a plurality of pixels PX may be located in the non-display area NPA. For example, the driver may include a gate driver, a light-emitting driver, a power voltage generator, a timing controller, and the like. The plurality of pixels PX may emit light based on signals transmitted from the driver.

The driving integrated circuit DIC may be located in the pad area PA on the substrate SUB. The driving integrated circuit DIC may convert a digital data signal among driving signals into an analog data signal and provide the converted analog data signal to the plurality of pixels PX. For example, the driving integrated circuit DIC may be a data driver.

The signal pads SE may be located in the pad area PA on the substrate SUB. The signal pads SE may be spaced apart from each other in the first direction DR1. Some of the signal pads SE may be connected to the driving integrated circuit DIC through a line, and the rest of the signal pads SE may be connected to the plurality of pixels PX through a line. For example, each of the signal pads SE may include a metal, an alloy, a metal nitride, a conductive metal oxide, a transparent conductive material, and the like. These may be used alone or in combination with each other.

The connection film CF may be located in the pad area PA on the substrate SUB. For example, the connection film CF may overlap a portion of the pad area PA. One end of the connection film CF may be electrically connected to the signal pads SE. The other end of the connection film CF may be electrically connected to an external device ED. That is, the driving signal, driving voltage, and the like generated from the external device ED may be provided to the driving integrated circuit DIC and the plurality of pixels PX through the connection film CF and the signal pads SE. For example, the connection film CF may include a flexible printed circuit board (FPCB), a printed circuit board (PCB), a flexible flat cable (FFC), or the like.

As illustrated in FIG. 3, the external device ED may be electrically connected to the display device DD. For example, the external device ED may be electrically connected to the display device DD through the connection film CF. The external device ED may generate the driving signal and the driving voltage to display an image on the display device DD.

In FIG. 1, the driving integrated circuit DIC is illustrated as being located in a chip on plastic (COP) method or a chip on glass (COG) method, but the configuration of the present disclosure is not limited thereto. For example, the driving integrated circuit DIC may be arranged in a chip-on-film (COF) method.

In this specification, a plane may be defined by the first direction DR1 and the second direction DR2, which crosses the first direction DR1. For example, the first direction DR1 may be perpendicular to the second direction DR2.

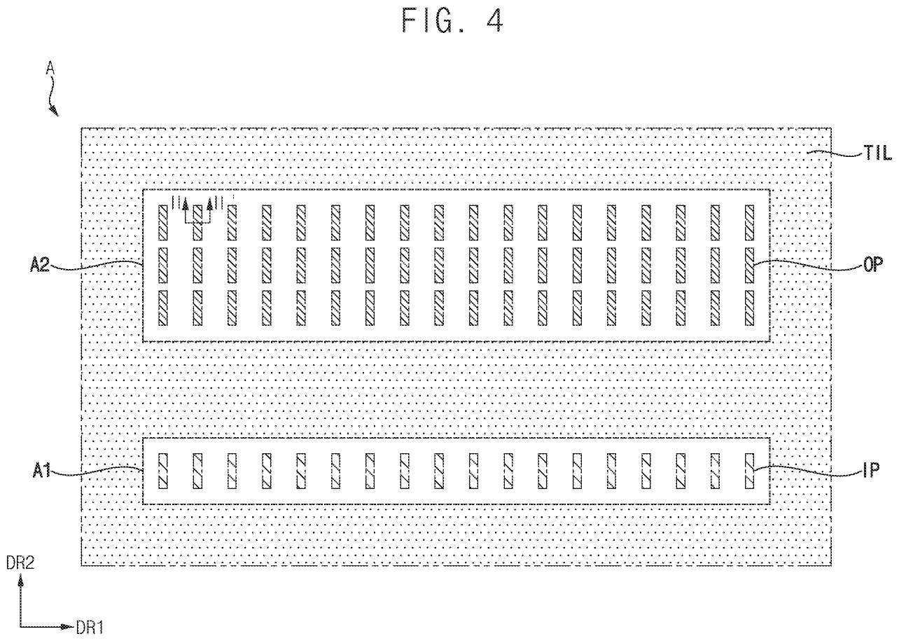

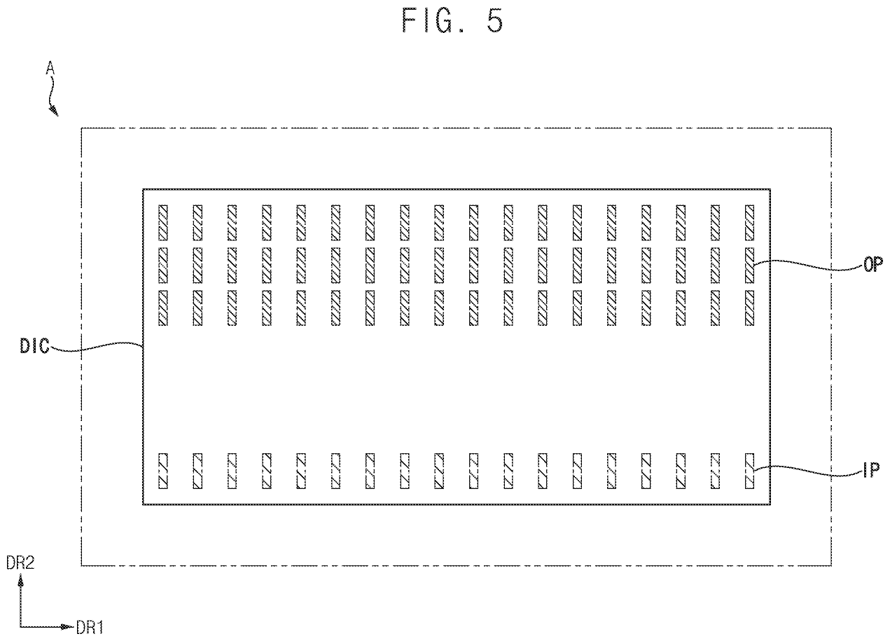

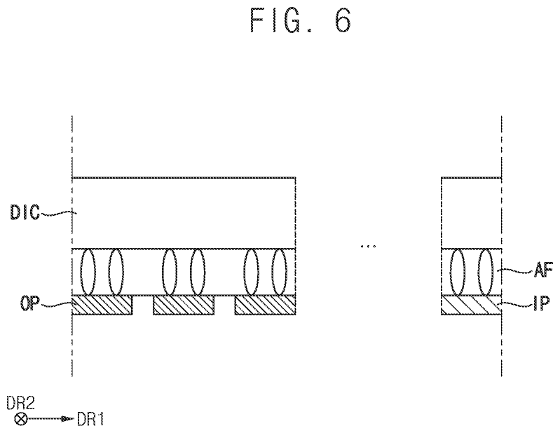

FIGS. 4 and 5 are enlarged plan views of an example of area A of FIG. 1. FIG. 6 is a cross-sectional view illustrating an example in which an integrated circuit is located on a plurality of pads of FIG. 5.

Referring to FIGS. 1, 4, 5, and 6, a plurality of pads may be located in the pad area PA on the substrate SUB. The plurality of pads may be repeatedly arranged along the first and second directions DR1 and DR2. The plurality of pads may include a plurality of input pads IP and a plurality of output pads OP.

The pad area PA may include a first area A1 and a second area A2. The plurality of input pads IP may be located in the first area A1. The plurality of output pads OP may be located in the second area A2. For example, each of the first area A1 and the second area A2 may extend in the first direction DR1, and may be spaced apart from each other along the second direction DR2.

The plurality of input pads IP may be spaced apart from each other in a line along the first direction DR1 in the first area A1. The plurality of output pads OP may be spaced apart from each other, and may be arranged in three lines along the first direction DR1 in the second area A2. However, the present disclosure is not limited thereto, and the plurality of input pads IP may be spaced apart from each other and arranged in two or more lines along the first direction DR1, and/or the plurality of output pads OP may be spaced apart from each other and arranged in one line, two lines, or four or more lines along the first direction DR1.

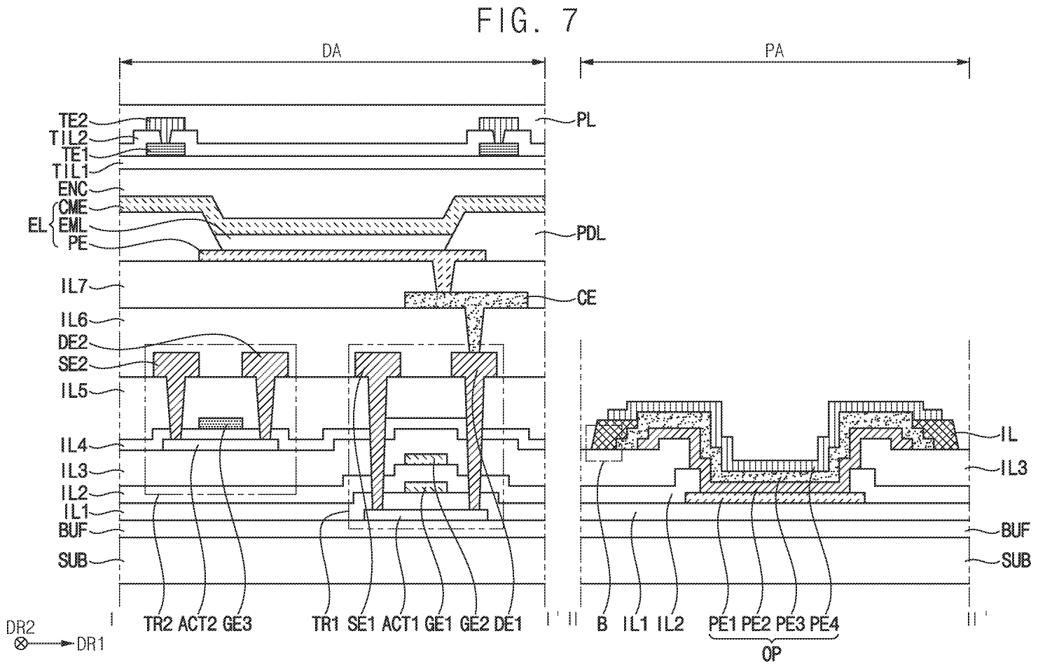

In one or more embodiments, a touch insulating layer TIL may be omitted from each of the first area A1 and the second area A2. That is, each of the first area A1 and the second area A2 may be an area from which the touch insulating layer TIL is removed. In this case, the touch insulating layer TIL may be entirely located in the remaining areas of the pad area PA not including the first area A1 and the second area A2. The touch insulating layer TIL may correspond to the first and second touch insulating layers TIL1 and TIL2 illustrated in FIG. 7.

The driving integrated circuit DIC may be located on the plurality of input pads IP and the plurality of output pads OP. The driving integrated circuit DIC may be electrically connected to the plurality of input pads IP and the plurality of output pads OP through a conductive film AF. For example, the conductive film AF may be an anisotropic conductive film. The driving integrated circuit DIC may output an output signal generated based on an input signal transmitted through the plurality of input pads IP through the plurality of output pads OP (see FIGS. 5 and 6).

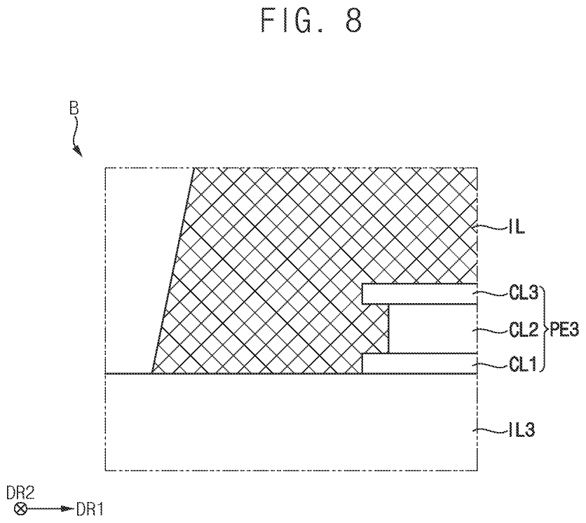

FIG. 7 is a cross-sectional view taken along the line I-I′ of FIG. 1 and the line II-II′ of FIG. 4. FIG. 8 is an enlarged cross-sectional view of area B of FIG. 7. For example, FIG. 7 is a cross-sectional view illustrating a portion of the display area DA of the display device DD, and a portion of one pad (e.g., the output pad OP of FIGS. 4 and 5) among the plurality of pads in the pad area PA.

Referring to FIGS. 7 and 8, the display device DD according to one or more embodiments of the present disclosure may include the substrate SUB, a buffer layer BUF, a first transistor TR1, a second transistor TR2, first, second, third, fourth, fifth, sixth, and seventh insulating layers IL1, IL2, IL3, IL4, IL5, IL6, and IL7, a connection electrode CE, the output pad OP, an additional insulating layer IL, a pixel-defining layer PDL, a light-emitting element EL, an encapsulation layer ENC, the first touch insulating layer TIL1, the second touch insulating layer TIL2, first touch electrodes TE1, second touch electrodes TE2, and a protective layer PL.

Here, the first transistor TR1 may include a first active pattern ACT1, a first gate electrode GE1, a second gate electrode GE2, a first source electrode SE1, and a first drain electrode DE1. The second transistor TR2 may include a second active pattern ACT2, a third gate electrode GE3, a second source electrode SE2, and a second drain electrode DE2. The light-emitting element EL may include a pixel electrode PE, a light-emitting layer EML, and a common electrode CME. The output pad OP may include first, second, third, and fourth pad electrodes PE1, PE2, PE3, and PE4.

The substrate SUB may include a transparent material or an opaque material. The substrate SUB may be made of a transparent resin substrate. Examples of the transparent resin substrate include polyimide substrates and the like. In this case, the polyimide substrate may include a first organic layer, a first barrier layer, and a second organic layer. Alternatively, the substrate SUB may include a quartz substrate, a synthetic quartz substrate, a calcium fluoride substrate, an F-doped quartz substrate, a soda-lime glass substrate, a non-alkali glass substrate, and the like. These may be used alone or in combination with each other.

The buffer layer BUF may be located on the substrate SUB. The buffer layer BUF may reduce or prevent diffusion of metal atoms or impurities from the substrate SUB into the first and second transistors TR1 and TR2. In addition, the buffer layer BUF may improve flatness of the surface of the substrate SUB when the surface of the substrate SUB is not uniform. For example, the buffer layer BUF may include an inorganic material, such as silicon oxide, silicon nitride, silicon oxynitride, and the like. These may be used alone or in combination with each other.

The first active pattern ACT1 may be located in the display area DA on the buffer layer BUF. In one or more embodiments, the first active pattern ACT1 may include an inorganic semiconductor, such as amorphous silicon, polycrystalline silicon, and the like. For example, the first active pattern ACT1 may have a first source region, a first drain region, and a first channel region positioned between the first source region and the first drain region.

The first insulating layer IL1 may be located on the buffer layer BUF. The first insulating layer IL1 may cover the first active pattern ACT1, and may be located along the profile of the first active pattern ACT1 to have a substantially uniform thickness. Alternatively, the first insulating layer IL1 may sufficiently cover the first active pattern ACT1, and may have a substantially flat upper surface without creating a step around the first active pattern ACT1. For example, the first insulating layer IL1 may include an inorganic material, such as silicon oxide (SiOₓ), silicon nitride (SiNₓ), silicon carbide (SiCₓ), silicon oxynitride (SiOₓN_{y}), silicon oxycarbide (SiOₓC_{y}), and the like. These may be used alone or in combination with each other. The first insulating layer IL1 may be defined as a first gate-insulating layer.

The first gate electrode GE1 may be located in the display area DA on the first insulating layer IL1. The first gate electrode GE1 may overlap the first channel region of the first active pattern ACT1. The first gate electrode GE1 may include a metal, an alloy, a metal nitride, a conductive metal oxide, a transparent conductive material, and the like. Examples of the metal include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride include aluminum nitride (AlNₓ), tungsten nitride (WNₓ), chromium nitride (CrNₓ), and the like. These may be used alone or in combination with each other.

The first pad electrode PE1 may be located in the pad area PA on the first insulating layer IL1. The first pad electrode PE1 may include the same material as the first gate electrode GE1. That is, the first pad electrode PE1 may be formed through the same process as the first gate electrode GE1.

The second insulating layer IL2 may be located on the first insulating layer IL1. The second insulating layer IL2 may cover the first gate electrode GE1 and may be located along the profile of the first gate electrode GE1 to have a substantially uniform thickness. Alternatively, the second insulating layer IL2 may sufficiently cover the first gate electrode GE1, and may have a substantially flat upper surface without creating a step around the first gate electrode GE1. In addition, the second insulating layer IL2 may cover an edge of the first pad electrode PE1, and may expose a central portion of the first pad electrode PE1 in the pad area PA. For example, the second insulating layer IL2 may include an inorganic material, such as silicon oxide, silicon nitride, silicon oxynitride, and the like. These may be used alone or in combination with each other. The second insulating layer IL2 may be defined as a second gate-insulating layer.

The second gate electrode GE2 may be located in the display area DA on the second insulating layer IL2. The second gate electrode GE2 may overlap the first gate electrode GE1. For example, the second gate electrode GE2 may include a metal, an alloy, a metal nitride, a conductive metal oxide, a transparent conductive material, and the like. These may be used alone or in combination with each other.

The third insulating layer IL3 may be located on the second insulating layer IL2 and the second gate electrode GE2. The third insulating layer IL3 may cover the second gate electrode GE2, and may be located along the profile of the second gate electrode GE2 to have a substantially uniform thickness. Alternatively, the third insulating layer IL3 may sufficiently cover the second gate electrode GE2, and may have a substantially flat upper surface without creating a step around the second gate electrode GE2. In addition, the third insulating layer IL3 may cover an edge of the second insulating layer IL2, and may expose a central portion of the first pad electrode PE1 in the pad area PA. For example, the third insulating layer IL3 may include an inorganic material, such as silicon oxide, silicon nitride, silicon oxynitride, and the like. These may be used alone or in combination with each other. The third insulating layer IL3 may be defined as a first interlayer insulating layer.

The second active pattern ACT2 may be located in the display area DA on the third insulating layer IL3. In one or more embodiments, the second active pattern ACT2 may include a metal oxide semiconductor. For example, the second active pattern ACT2 may have a second source region, a second drain region, and a second channel region positioned between the second source region and the second drain region.

The metal oxide semiconductor may include a two-component compound (ABₓ), a ternary compound (ABₓC_{y}), a four-component compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide, (ITO), indium zinc tin oxide (IZTO), indium gallium zinc oxide (IGZO), and the like. These may be used alone or in combination with each other.

The fourth insulating layer IL4 may be located on the third insulating layer IL3. The fourth insulating layer IL4 may be located only in the display area DA. The fourth insulating layer IL4 may cover the second active pattern ACT2, and may be located along the profile of the second active pattern ACT2 to have a substantially uniform thickness. Alternatively, the fourth insulating layer IL4 may sufficiently cover the second active pattern ACT2, and may have a substantially flat upper surface without creating a step around the second active pattern ACT2. For example, the fourth insulating layer IL4 may include an inorganic material, such as silicon oxide, silicon nitride, silicon oxynitride, and the like. These may be used alone or in combination with each other. The fourth insulating layer IL4 may be defined as a third gate-insulating layer.

The third gate electrode GE3 may be located in the display area DA on the fourth insulating layer IL4. The third gate electrode GE3 may overlap the second channel region of the second active pattern ACT2. For example, the third gate electrode GE3 may include a metal, an alloy, a metal nitride, a conductive metal oxide, a transparent conductive material, and the like. These may be used alone or in combination with each other.

The fifth insulating layer IL5 may be located on the fourth insulating layer IL4. The fifth insulating layer IL5 may be located only in the display area DA. The fifth insulating layer IL5 may sufficiently cover the third gate electrode GE3, and may have a substantially flat upper surface without creating a step around the third gate electrode GE3. Alternatively, the fifth insulating layer IL5 may cover the third gate electrode GE3, and may be located along the profile of the third gate electrode GE3 to have a substantially uniform thickness. For example, the fifth insulating layer IL5 may include an inorganic material, such as silicon oxide, silicon nitride, silicon oxynitride, and the like. These may be used alone or in combination with each other. The fifth insulating layer IL5 may be defined as a second interlayer insulating layer.

The first source electrode SE1 and the first drain electrode DE1 may be located in the display area DA on the fifth insulating layer IL5. The first source electrode SE1 may be connected to the first source region of the first active pattern ACT1 through a contact hole penetrating a first portion of an inorganic insulating layer (e.g., the first, second, third, fourth, and fifth insulating layers IL1, IL2, IL3, IL4, and IL5). The first drain electrode DE1 may be connected to the first drain region of the first active pattern ACT1 through a contact hole penetrating a second portion of the inorganic insulating layer (e.g., the first, second, third, fourth, and fifth insulating layers IL1, IL2, IL3, IL4, and IL5). For example, each of the first source electrode SE1 and the first drain electrode DE1 may include a metal, an alloy, a metal nitride, a conductive metal oxide, a transparent conductive material, and the like. These may be used alone or in combination with each other. In one or more embodiments, each of the first source electrode SE1 and the first drain electrode DE1 may have a multilayer structure including Ti/Al/Ti.

The second source electrode SE2 and the second drain electrode DE2 may be located in the display area DA on the fifth insulating layer IL5. The second source electrode SE2 may be connected to the second source region of the second active pattern ACT2 through a contact hole penetrating a first portion of the fourth and fifth insulating layers IL4 and IL5. The second drain electrode DE2 may be connected to the second drain region of the second active pattern ACT2 through a contact hole penetrating a second portion of the fourth and fifth insulating layers IL4 and IL5. The second source electrode SE2 and the second drain electrode DE2 may include the same material as the first source electrode SE1 and the first drain electrode DE1, and may be located in the same layer as the first source electrode SE1 and the first drain electrode DE1.

Accordingly, the first transistor TR1 including the first active pattern ACT1, the first gate electrode GE1, the second gate electrode GE2, the first source electrode SE1, and the first drain electrode DE1 may be located in the display area DA. The second transistor TR2 including the second active pattern ACT2, the third gate electrode GE3, the second source electrode SE2, and the second drain electrode DE2 may be located in the display area DA. Here, the first transistor TR1 may be defined as a driving transistor, and the second transistor TR2 may be defined as a switching transistor.

The second pad electrode PE2 may be located in the pad area PA on the first pad electrode PE1. For example, the second pad electrode PE2 may directly contact a central portion of the first pad electrode PE1. The second pad electrode PE2 may extend along side surfaces of the second and third insulating layers IL2 and IL3 to a portion of an upper surface of the third insulating layer IL3. In addition, the second pad electrode PE2 may include the same material as the first source electrode SE1, the second source electrode SE2, the first drain electrode DE1, and the second drain electrode DE2. That is, the second pad electrode PE2 may be formed through the same process as the first source electrode SE1, the second source electrode SE2, the first drain electrode DE1, and the second drain electrode DE2.

The sixth insulating layer IL6 may be located on the fifth insulating layer IL5. The sixth insulating layer IL6 may sufficiently cover the first source electrode SE1, the first drain electrode DE1, the second source electrode SE2, and the second drain electrode DE2. The sixth insulating layer IL6 may include an organic material. For example, the sixth insulating layer IL6 may include an organic material, such as polyimide resin, polyamide resin, siloxane resin, epoxy resin, and the like. These may be used alone or in combination with each other. The sixth insulating layer IL6 may be defined as a first organic insulating layer.

The connection electrode CE may be located on the sixth insulating layer IL6. The connection electrode CE may be connected to the first drain electrode DE1 through a contact hole penetrating the sixth insulating layer IL6. Accordingly, the connection electrode CE may electrically connect the first transistor TR1 and the light-emitting element EL. For example, the connection electrode CE may include a metal, an alloy, a metal nitride, a conductive metal oxide, a transparent conductive material, and the like. These may be used alone or in combination with each other. In one or more embodiments, the connection electrode CE may have a multilayer structure including Ti/Al/Ti.

The third pad electrode PE3 may be located in the pad area PA on the second pad electrode PE2. For example, the third pad electrode PE3 may directly contact the second pad electrode PE2. The third pad electrode PE3 may be located to completely cover the second pad electrode PE2. In addition, the third pad electrode PE3 may include the same material as the connection electrode CE. That is, the third pad electrode PE3 may be formed through the same process as the connection electrode CE.

In one or more embodiments, the third pad electrode PE3 may include a first conductive layer CL1 including Ti, a second conductive layer CL2 located on the first conductive layer CL1 and including Al, and a third conductive layer CL3 located on the second conductive layer CL2 including Al. For example, the first and third conductive layers CL1 and CL3 may protrude more than the second conductive layer CL2 in the first direction DR1 and/or in a direction (e.g., a direction toward the insulating layer IL) opposite to the first direction DR1. Accordingly, each of the first and third conductive layers CL1 and CL3 may form a tip.

The seventh insulating layer IL7 may be located on the sixth insulating layer IL6. The seventh insulating layer IL7 may have a substantially flat upper surface. The seventh insulating layer IL7 may include an organic material. For example, the seventh insulating layer IL7 may include an organic material, such as polyimide resin, polyamide resin, siloxane resin, epoxy resin, and the like. These may be used alone or in combination with each other. The seventh insulating layer IL7 may be defined as a second organic insulating layer.

The additional insulating layer IL may be located in the pad area PA on the third insulating layer IL3. The additional insulating layer IL may cover an edge of the third pad electrode PE3. For example, the additional insulating layer IL may cover the second conductive layer CL2 (e.g., may contact a side surface of the second conductive layer CL2) among the first, second, and third conductive layers CL1, CL2, and CL3 of the third pad electrode PE3 so as not to be exposed to the outside. Accordingly, short failure and the like due to tip formation of the first and third conductive layers CL1 and CL3 may be improved.

In one or more embodiments, an upper surface of the additional insulating layer IL may directly contact the fourth pad electrode PE4. A detailed description of this will be described later.

The additional insulating layer IL may include an organic material. For example, the additional insulating layer IL may include the same material as the seventh additional insulating layer IL. That is, the additional insulating layer IL may be formed through the same process as the seventh insulating layer IL7.

The pixel electrode PE may be located in the display area DA on the seventh insulating layer IL7. The pixel electrode PE may be connected to the connection electrode CE through a contact hole penetrating the seventh insulating layer IL7. For example, the pixel electrode PE may include a metal, an alloy, a metal nitride, a conductive metal oxide, a transparent conductive material, and the like. These may be used alone or in combination with each other. For example, the pixel electrode PE may act as an anode.

The pixel-defining layer PDL may be located on the seventh insulating layer IL7. The pixel-defining layer PDL may cover an edge of the pixel electrode PE. For example, the pixel-defining layer PDL may include an inorganic material or an organic material. In one or more embodiments, the pixel-defining layer PDL may include an organic material, such as an epoxy resin, a siloxane resin, and the like. These may be used alone or in combination with each other. In one or more other embodiments, the pixel-defining layer PDL may further include a light-blocking material containing a black pigment, black dye, and the like.

The light-emitting layer EML may be located on the pixel electrode PE. The light-emitting layer EML may include an organic material that emits light of a color (e.g., a predetermined color). For example, the light-emitting layer EML may include an organic material that emits at least one of red light, green light, and blue light.

The common electrode CME may be located on the pixel-defining layer PDL and the light-emitting layer EML. For example, the common electrode CME may include a metal, an alloy, a metal nitride, a conductive metal oxide, a transparent conductive material, and the like. These may be used alone or in combination with each other. For example, the common electrode CME may operate as a cathode.

Accordingly, the light-emitting element EL including the pixel electrode PE, the light-emitting layer EML, and the common electrode CME may be located in the display area DA.

The encapsulation layer ENC may be located on the common electrode CME. The encapsulation layer ENC may reduce or prevent impurities, moisture, and the like from permeating the light-emitting element EL from the outside. The encapsulation layer ENC may include at least one inorganic layer and at least one organic layer. For example, the inorganic layer may include silicon oxide, silicon nitride, silicon oxynitride, and the like. These may be used alone or in combination with each other. The organic layer may include a polymer cured material, such as polyacrylate.

The first touch insulating layer TIL1 may be located on the encapsulation layer ENC. The first touch insulating layer TIL1 may include an inorganic material. For example, the first touch insulating layer TIL1 may include silicon oxide, silicon nitride, silicon oxynitride, and the like. These may be used alone or in combination with each other.

In one or more embodiments, the first touch insulating layer TIL1 may be entirely located in the display area DA, and may be omitted from a partial area (e.g., the first area A1 and the second area A2 of FIGS. 4 and 5) of the pad area PA in which the output pad OP and input pad (e.g., the input pad IP of FIGS. 4 and 5) are located.

The first touch electrodes TE1 may be located in the display area DA on the first touch insulating layer TIL1. For example, each of the first touch electrodes TE1 may include a metal, an alloy, a metal nitride, a conductive metal oxide, a transparent conductive material, and the like. These may be used alone or in combination with each other. The first touch electrode TE1 may be defined as a lower touch electrode.

The second touch insulating layer TIL2 may be located on the first touch insulating layer TIL1. The second touch insulating layer TIL2 may cover the first touch electrodes TE1. The second touch insulating layer TIL2 may include an inorganic material. For example, the second touch insulating layer TIL2 may include silicon oxide, silicon nitride, silicon oxynitride, and the like. These may be used alone or in combination with each other.

In one or more embodiments, the second touch insulating layer TIL2 may be entirely located in the display area DA, and may be omitted from a partial area (e.g., the first area A1 and the second area A2 of FIGS. 4 and 5) of the pad area PA in which the output pad OP and input pad (e.g., the input pad IP of FIGS. 4 and 5) are located.

The second touch electrodes TE2 may be located in the display area DA on the second touch insulating layer TIL2. The second touch electrodes TE2 may be connected to the first touch electrodes TE1 through contact holes penetrating the second touch insulating layer TIL2. The first touch electrodes TE1 and the second touch electrodes TE2 may sense an external touch, and may transfer the external touch to a touch driver. For example, each of the second touch electrodes TE2 may include a metal, an alloy, a metal nitride, a conductive metal oxide, a transparent conductive material, and the like. These may be used alone or in combination with each other. The first touch electrode TE2 may be defined as an upper touch electrode.

The fourth pad electrode PE4 may be located in the pad area PA on the third pad electrode PE3. In one or more embodiments, an entire lower surface of the fourth pad electrode PE4 may directly contact the third pad electrode PE3 and the additional insulating layer IL. That is, a touch insulating layer (e.g., the first and second touch insulating layers TIL1 and TIL2) may be omitted from between the third pad electrode PE3 and the fourth pad electrode PE4. The fourth pad electrode PE4 may include the same material as the second touch electrode TE2. That is, the fourth pad electrode PE4 may be formed through the same process as the second touch electrode TE2.

The protective layer PL may be located on the second touch insulating layer TIL2. The protective layer PL may cover the second touch electrodes TE2. The protective layer PL may protect the first touch electrodes TE1 and the second touch electrodes TE2 from external impact. The protective layer PL may include an organic material. For example, the protective layer PL may include an organic material, such as polyacrylic resin, polyimide resin, acrylic resin, and the like. These may be used alone or in combination with each other.

Accordingly, the first touch insulating layer TIL1, the first touch electrodes TE1, the second touch insulating layer TIL2, the second touch electrodes TE2, and the protective layer PL may constitute a touch layer.

According to the comparative example, the first and second touch insulating layers TIL1 and TIL2 may be located, not only in the display area DA, but also in a partial area (e.g., the first area A1 and the second area A2 of FIGS. 4 and 5) of the pad area PA. For example, the first and second touch insulating layers TIL1 and TIL2 may cover the additional insulating layer IL, and may also be located between the third and fourth pad electrodes PE3 and PE4 in the pad area PA. However, in this case, after the reliability evaluation is performed in a high-temperature and high-humidity environment, stress may be added to an area where the inorganic layers (e.g., the third insulating layer IL3 and the first and second touch insulating layers TIL1 and TIL2) are in contact with each other in the pad area PA due to moisture permeability and expansion of the additional insulating layer IL. Accordingly, lifting of a driving integrated circuit (e.g., the driving integrated circuit DIC of FIGS. 1 and 5) may occur.

In the display device DD according to one or more embodiments of the present disclosure, a plurality of pads each including the first, second, third, and fourth pad electrodes PE1, PE2, PE3, and PE4 sequentially stacked, and the additional insulating layer IL covering the third pad electrode PE3 and including an organic material may be located in the pad area PA. The additional insulating layer IL may directly contact the fourth pad electrode PE4. In addition, the entire lower surface of the fourth pad electrode PE4 may directly contact the third pad electrode PE3 and the additional insulating layer IL. That is, the first and second touch insulating layers TIL1 and TIL2 might not be located between the third pad electrode PE3 and the fourth pad electrode PE4. Accordingly, after the reliability evaluation of the display device DD is performed in a high-temperature and high-humidity environment, lifting of the driving integrated circuit DIC may be improved.

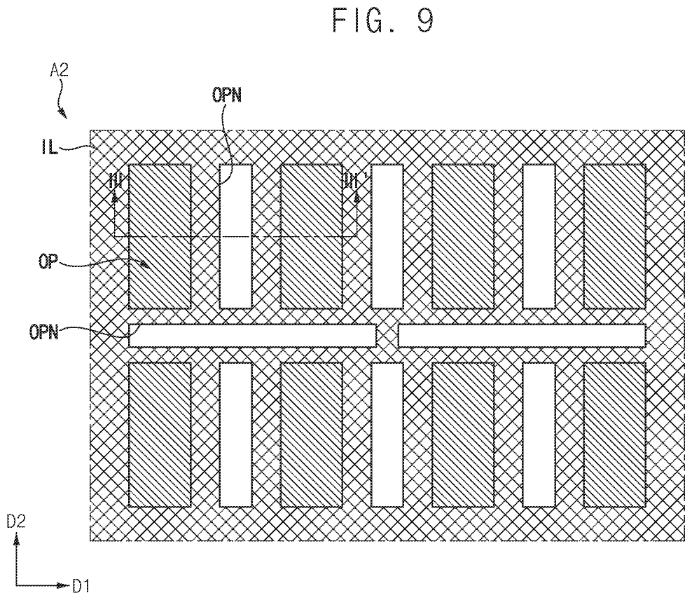

FIG. 9 is an enlarged plan view of a portion of a second area of FIG. 4. FIG. is a cross-sectional view taken along the line III-III′ of FIG. 9. For example, FIG. 9 is a plan view of the output pads OP of FIGS. 4 and 7 and the additional insulating layer IL of FIG. 7.

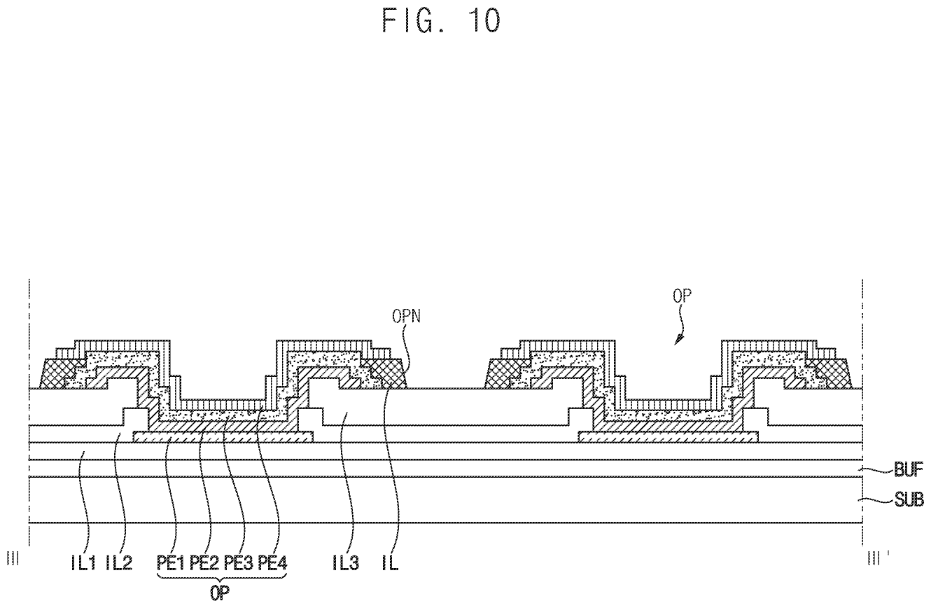

Referring to FIGS. 9 and 10, a plurality of openings OPN positioned between adjacent output pads OP among the output pads OP may be defined in the additional insulating layer IL. Each of the plurality of openings OPN may expose at least a portion of an upper surface of the third insulating layer IL3.

In one or more embodiments, first openings among the plurality of openings OPN may be positioned between the output pads OP arranged along the first direction DR1, and second openings among the plurality of openings OPN may be positioned between the output pads OP arranged in a first row and the output pads OP arranged in a second row that is adjacent to the first row. Each of the first openings may extend in the second direction DR2, and each of the second openings may extend in the first direction DR1.

Although FIG. 9 shows a plan view of the additional insulating layer IL positioned in the second area A2 in which the output pad OP is located, an insulating layer including an organic material, and in which a plurality of openings are defined, may also be located in a first area (e.g., the first area A1 of FIGS. 4 and 5) in which an input pad (e.g., the input pad IP of FIGS. 4 and 5) is located.

In addition, the stack structure of the output pad OP illustrated in FIG. 10 may be substantially the same as the stack structure of the output pad OP described with reference to FIG. 7.

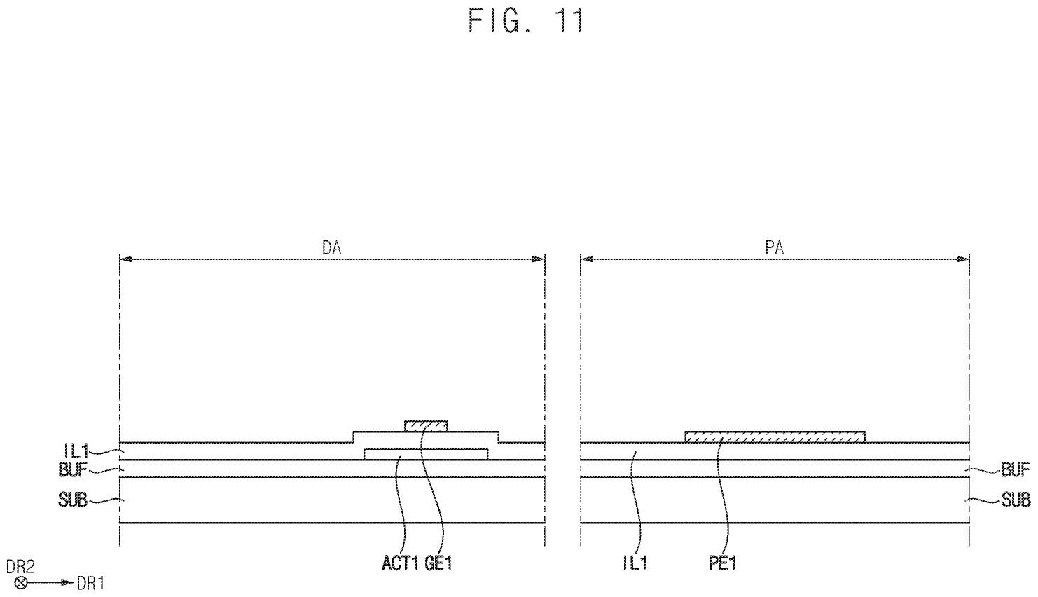

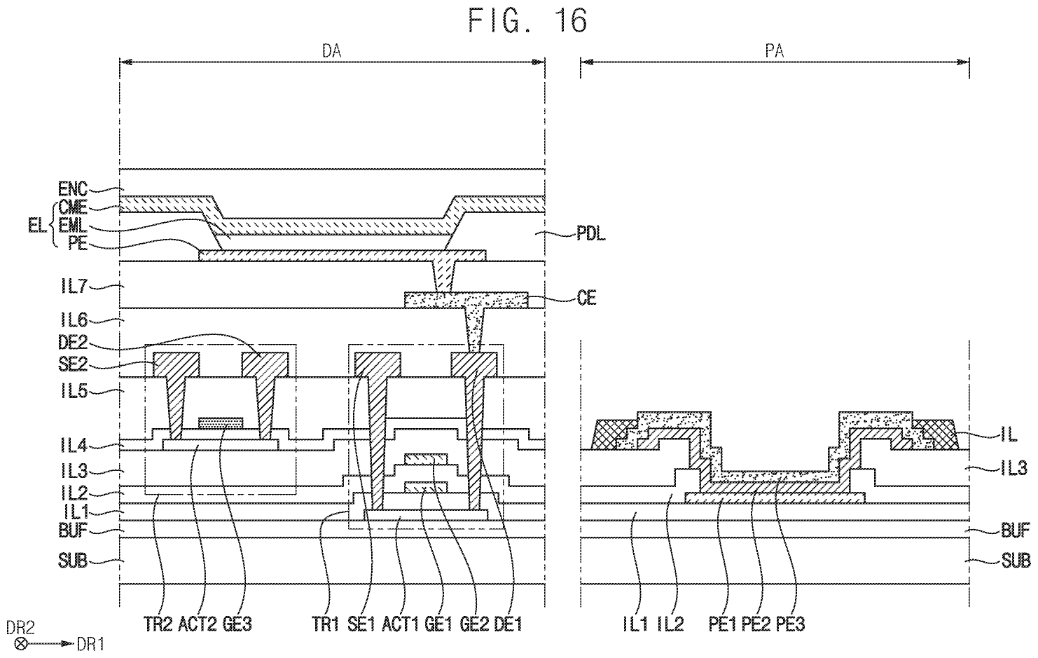

FIGS. 11, 12, 13, 14, 15, 16, 17, 18, and 19 are cross-sectional views illustrating a method for manufacturing the display device of FIG. 7.

Referring to FIG. 11, the buffer layer BUF may be formed on the substrate SUB. The first active pattern ACT1 may be formed in the display area DA on the buffer layer BUF. For example, the first active pattern ACT1 may be formed using an inorganic semiconductor.

The first insulating layer IL1 may be formed on the buffer layer BUF. The first insulating layer IL1 may be formed in the display area DA and the pad area PA. For example, the first insulating layer IL1 may be formed using an inorganic material.

The first gate electrode GE1 may be formed in the display area DA on the first insulating layer IL1. The first gate electrode GE1 may overlap the first channel region of the first active pattern ACT1. For example, the first gate electrode GE1 may be formed using a metal, an alloy, a metal nitride, a conductive metal oxide, a transparent conductive material, and the like.

The first pad electrode PE1 may be formed in the pad area PA on the first insulating layer IL1. The first pad electrode PE1 and the first gate electrode GE1 may be concurrently or substantially simultaneously formed through the same process.

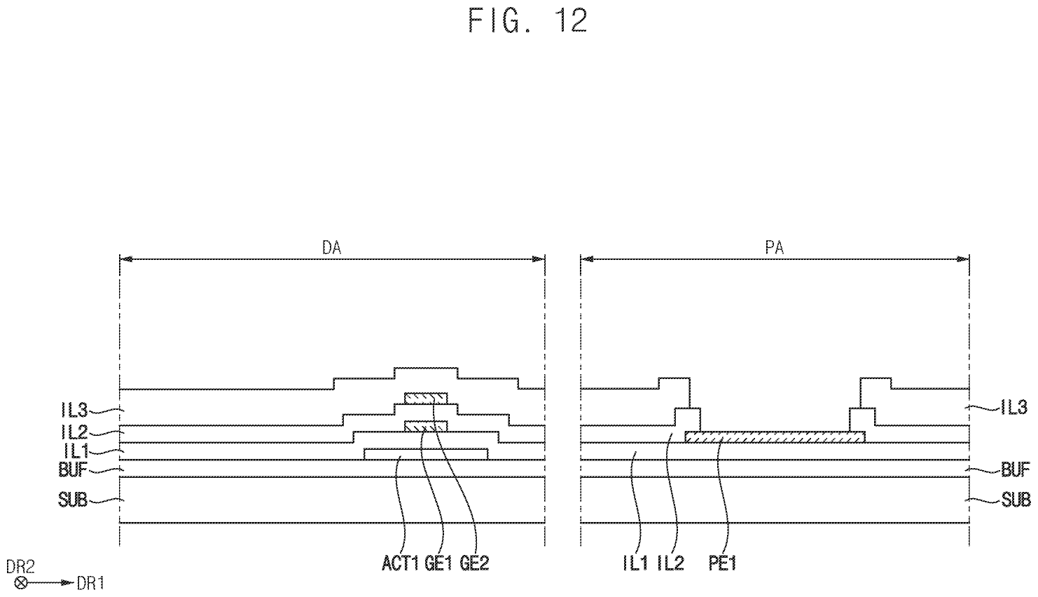

Referring to FIG. 12, the second insulating layer IL2 may be formed on the first insulating layer IL1. After the second insulating layer IL2 is entirely formed in the display area DA and the pad area PA, a portion of the second insulating layer IL2 positioned in the pad area PA may be removed through an etching process. Accordingly, the second insulating layer IL2 may cover an edge of the first pad electrode PE1, and may expose a central portion of the first pad electrode PE1 in the pad area PA. For example, the second insulating layer IL2 may be formed using an inorganic material.

The second gate electrode GE2 may be formed in the display area DA on the second insulating layer IL2. The second gate electrode GE2 may overlap the first gate electrode GE1. For example, the second gate electrode GE2 may be formed using a metal, an alloy, a metal nitride, a conductive metal oxide, a transparent conductive material, and the like.

The third insulating layer IL3 may be formed on the second insulating layer IL2. After the third insulating layer IL3 is entirely formed in the display area DA and the pad area PA, a portion of the third insulating layer IL3 positioned in the pad area PA may be removed through an etching process. Accordingly, the third insulating layer IL3 may cover the edge of the second insulating layer IL2, and may expose the central portion of the first pad electrode PE1 in the pad area PA. For example, the third insulating layer IL3 may be formed using an inorganic material.

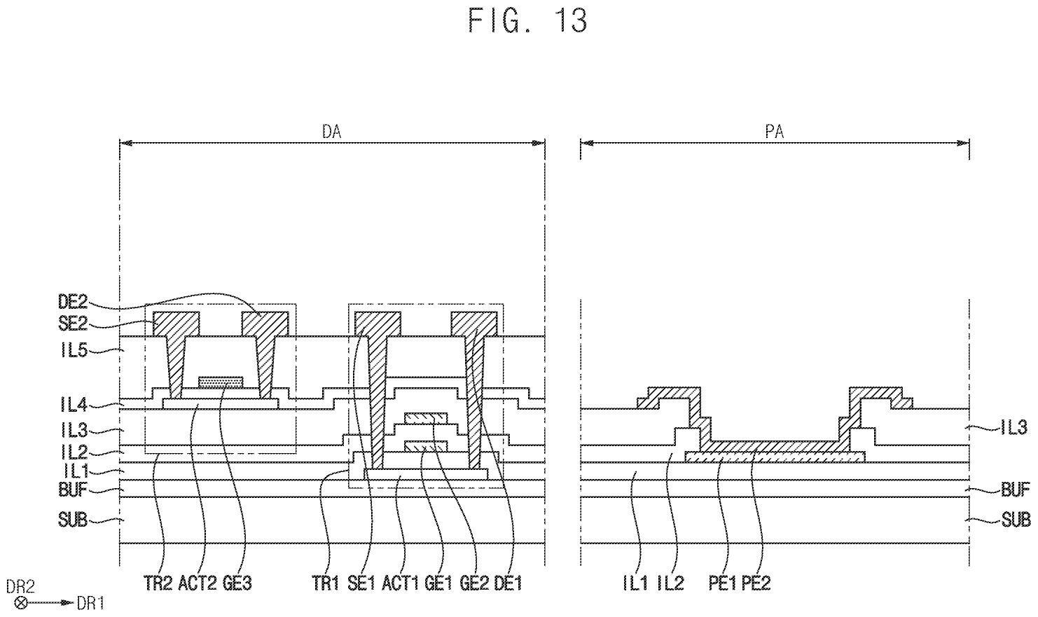

Referring to FIG. 13, the second active pattern ACT2 may be formed in the display area DA on the third insulating layer IL3. For example, the second active pattern ACT2 may be formed using a metal oxide semiconductor.

The fourth insulating layer IL4 may be formed on the third insulating layer IL3. The fourth insulating layer IL4 may cover the second active pattern ACT2. The fourth insulating layer IL4 may be formed only in the display area DA. For example, the fourth insulating layer IL4 may be formed using an inorganic material.

The third gate electrode GE3 may be formed in the display area DA on the fourth insulating layer IL4. The third gate electrode GE3 may overlap the second channel region of the second active pattern ACT2. For example, the third gate electrode GE3 may be formed using a metal, an alloy, a metal nitride, a conductive metal oxide, a transparent conductive material, and the like.

The fifth insulating layer IL5 may be formed on the fourth insulating layer IL4. The fifth insulating layer IL5 may cover the third gate electrode GE3. The fifth insulating layer IL5 may be formed only in the display area DA. For example, the fifth insulating layer IL5 may be formed using an inorganic material.

The first source electrode SE1 and the first drain electrode DE1 may be formed in the display area DA on the fifth insulating layer IL5. The first source electrode SE1 may be connected to the first source region of the first active pattern ACT1 through a contact hole formed by removing a first portion of the first, second, third, fourth, and fifth insulating layers IL1, IL2, IL3, IL4, and IL5. The first drain electrode DE1 may be connected to the first drain region of the first active pattern ACT1 through a contact hole formed by removing a second portion of the first, second, third, fourth, and fifth insulating layers IL1, IL2, IL3, IL4, and IL5.

The second source electrode SE2 and the second drain electrode DE2 may be formed in the display area DA on the fifth insulating layer IL5. The second source electrode SE2 may be connected to the second source region of the second active pattern ACT2 through a contact hole formed by removing a first portion of the fourth and fifth insulating layers IL4 and IL5. The second drain electrode DE2 may be connected to the second drain region of the second active pattern ACT2 through a contact hole formed by removing a second portion of the fourth and fifth insulating layers IL4 and IL5.

For example, each of the first source electrode SE1, the first drain electrode DE1, the second source electrode SE2, and the second drain electrode DE2 may be formed using a metal, an alloy, a metal nitride, a conductive metal oxide, a transparent conductive material, and the like.

The second pad electrode PE2 may be formed on the first pad electrode PE1. For example, the second pad electrode PE2 may be formed to directly contact the central portion of the first pad electrode PE1 exposed by the second and third insulating layers IL2 and IL3 in the pad area PA. The second pad electrode PE2 may be concurrently or substantially simultaneously formed through the same process as the first source electrode SE1, the first drain electrode DE1, the second source electrode SE2, and the second drain electrode DE2.

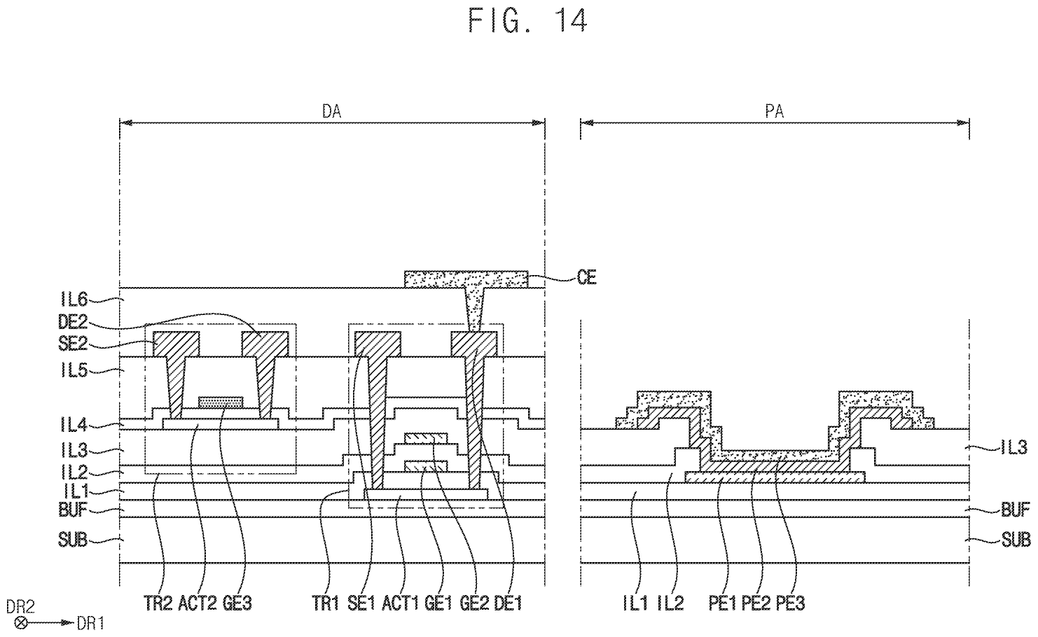

Referring to FIG. 14, the sixth insulating layer IL6 may be formed on the fifth insulating layer IL5. The sixth insulating layer IL6 may cover the first source electrode SE1, the first drain electrode DE1, the second source electrode SE2, and the second drain electrode DE2. The sixth insulating layer IL6 may be formed only in the display area DA. For example, the sixth insulating layer IL6 may be formed using an organic material.

The connection electrode CE may be formed in the display area DA on the sixth insulating layer IL6. The connection electrode CE may be connected to the first drain electrode DE1 through a contact hole formed by removing a portion of the sixth insulating layer IL6. For example, the connection electrode CE may have a multilayer structure formed using Ti/Al/Ti.

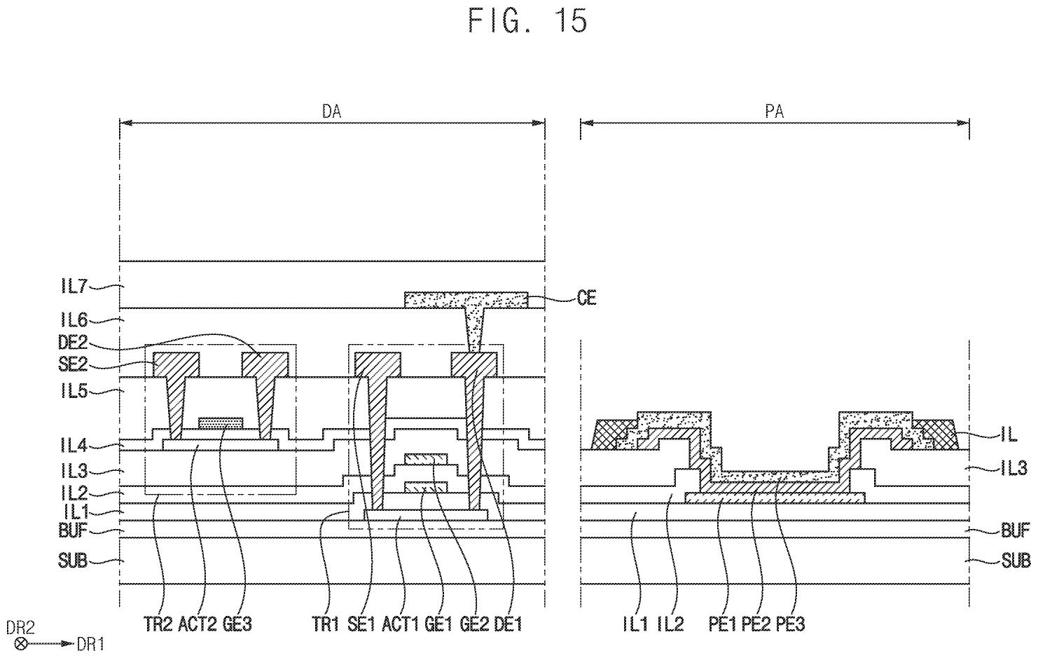

Referring to FIG. 15, the seventh insulating layer IL7 may be formed on the sixth insulating layer IL6. The seventh insulating layer IL7 may cover the connection electrode CE in the display area DA. For example, the seventh insulating layer IL7 may be formed using an organic material.

The additional insulating layer IL may be formed in the pad area PA on the third insulating layer IL3. The additional insulating layer IL may be formed to cover an edge of the third pad electrode PE3.

The additional insulating layer IL may be formed using the same material as the seventh insulating layer IL7. That is, after the seventh insulating layer IL7 is entirely formed in the display area DA and the pad area PA, a portion of the seventh insulating layer IL7 positioned in the pad area PA is removed, thereby forming the additional insulating layer IL in the pad area PA.

The pixel electrode PE may be formed in the display area DA on the seventh insulating layer IL7. The pixel electrode PE may be connected to the connection electrode CE through a contact hole formed by removing a portion of the seventh insulating layer IL7. For example, the pixel electrode PE may be formed using a metal, an alloy, a metal nitride, a conductive metal oxide, a transparent conductive material, and the like.

The pixel-defining layer PDL may be formed on the seventh insulating layer IL7. The pixel-defining layer PDL may cover an edge of the pixel electrode PE. For example, the pixel-defining layer PDL may be formed using an organic material containing a light-blocking material.

The light-emitting layer EML may be formed on the pixel electrode PE. The light-emitting layer EML may be formed using an organic material that emits light of a color (e.g., a predetermined color).

The common electrode CME may be formed on the pixel-defining layer PDL and the light-emitting layer EML. For example, the common electrode CME may be formed using a metal, an alloy, a metal nitride, a conductive metal oxide, a transparent conductive material, and the like.

The encapsulation layer ENC may be formed on the common electrode CME. The encapsulation layer ENC may include at least one inorganic layer and at least one organic layer.

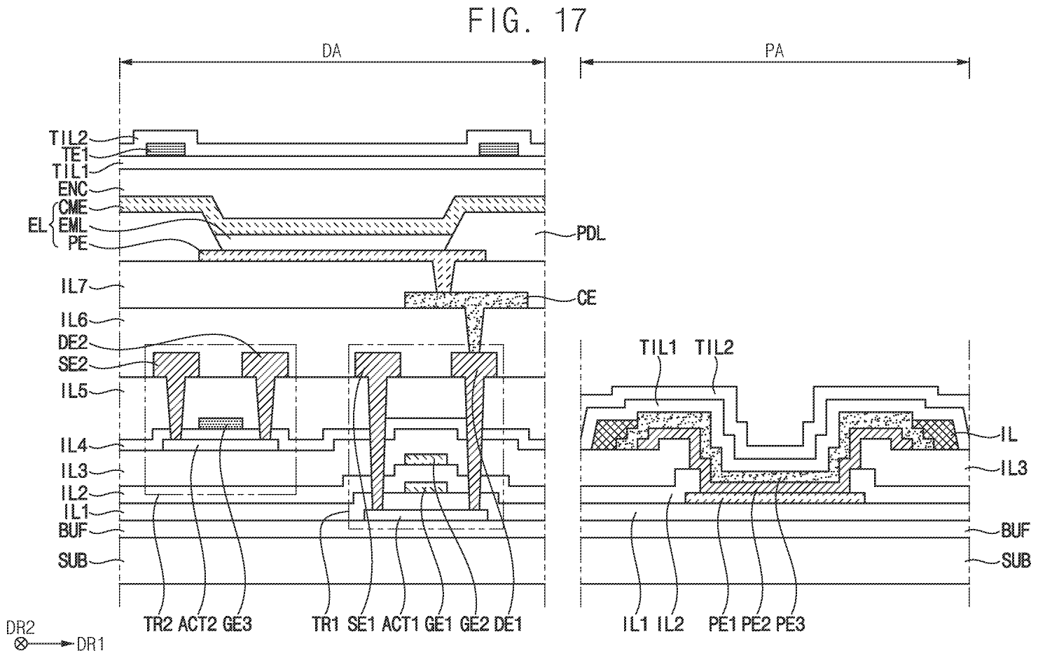

Referring to FIG. 17, the first touch insulating layer TIL1 may be formed on the encapsulation layer ENC. The first touch insulating layer TIL1 may also be formed on the third insulating layer IL3, the additional insulating layer IL and the third pad electrode PE3 in the pad area PA. For example, the first touch insulating layer TIL1 may be formed using an inorganic material.

The first touch electrodes TE1 may be formed in the display area DA on the first touch insulating layer TIL1. For example, each of the first touch electrodes TE1 may be formed using a metal, an alloy, a metal nitride, a conductive metal oxide, a transparent conductive material, and the like.

The second touch insulating layer TIL2 may be formed on the first touch insulating layer TIL1. The second touch insulating layer TIL2 may cover the first touch electrodes TE1, and may be formed in the display area DA and the pad area PA.

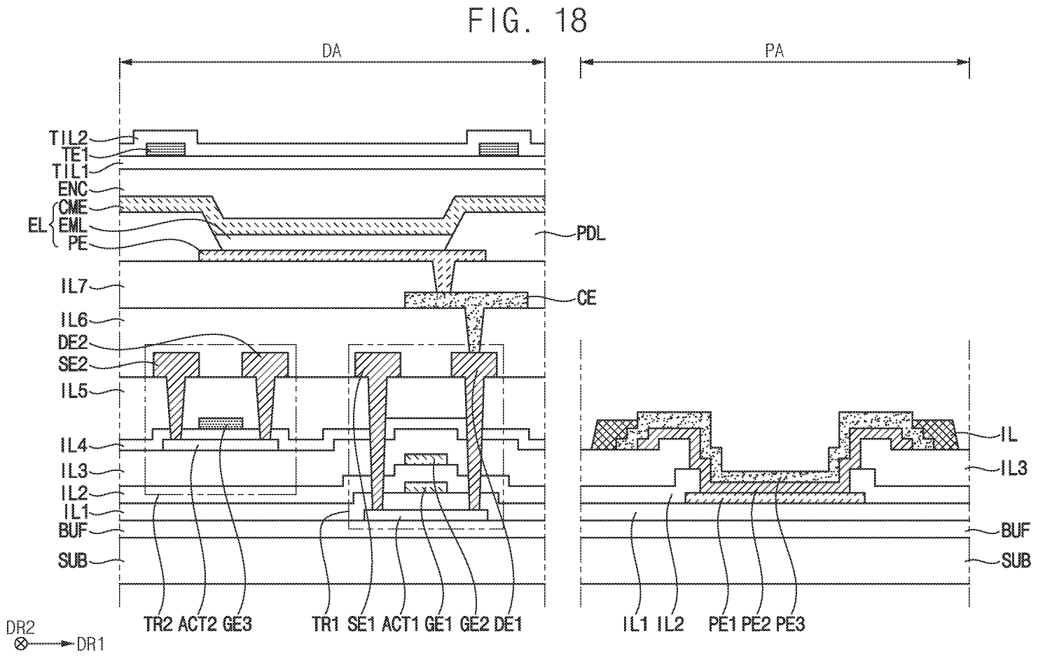

Referring to FIG. 18, in one or more embodiments, a portion of the first and second touch insulating layers TIL1 and TIL2 positioned in a portion of the pad area PA may be removed through an etching process. For example, the portion of the first and second touch insulating layers TIL1 and TIL2 formed in an area (e.g., the first area A1 and the second area A2) in which the first, second, and third pad electrodes PE1, PE2 and PE3 are positioned may be removed through the etching process. Accordingly, the first and second touch insulating layers TIL1 and TIL2 may not remain on the third pad electrode PE3. In this case, a portion of the upper surface of the third pad electrode PE3 may be exposed.

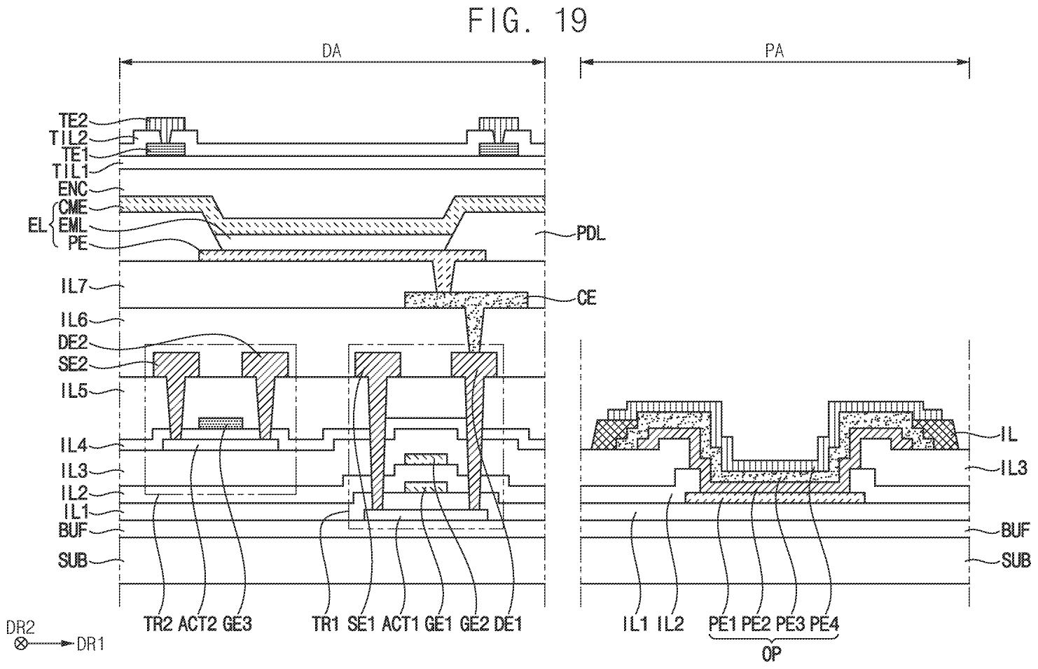

Referring to FIG. 19, the second touch electrodes TE2 may be formed in the display area DA on the second touch insulating layer TIL2. The second touch electrodes TE2 may be respectively connected to the first touch electrodes TE1 through contact holes formed by removing a portion of the second touch insulating layer TIL2. For example, each of the second touch electrodes TE2 may be formed using a metal, an alloy, a metal nitride, a conductive metal oxide, a transparent conductive material, and the like.

The fourth pad electrode PE4 may be formed on the third pad electrode PE3 and the additional insulating layer IL. For example, the fourth pad electrode PE4 may be formed to directly contact the third pad electrode PE3 and the additional insulating layer IL. The fourth pad electrode PE4 may be concurrently or substantially simultaneously formed through the same process as the second touch electrodes TE2.

Referring back to FIG. 7, the protective layer PL may be formed on the second touch insulating layer TIL2. The protective layer PL may cover the second touch electrodes TE2 in the display area DA. The protective layer PL may be formed using an organic material.

Accordingly, the display device DD shown in FIG. 7 may be manufactured.

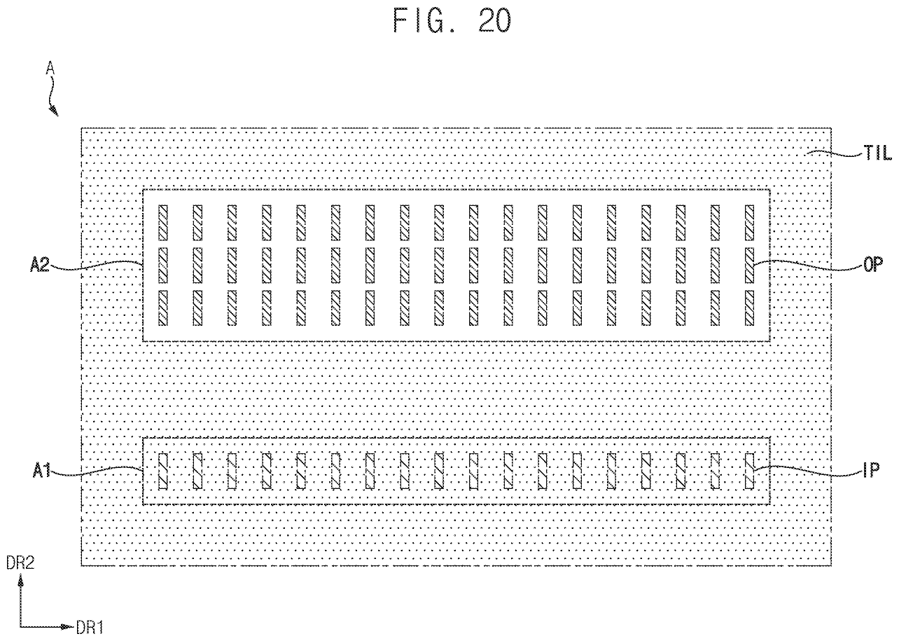

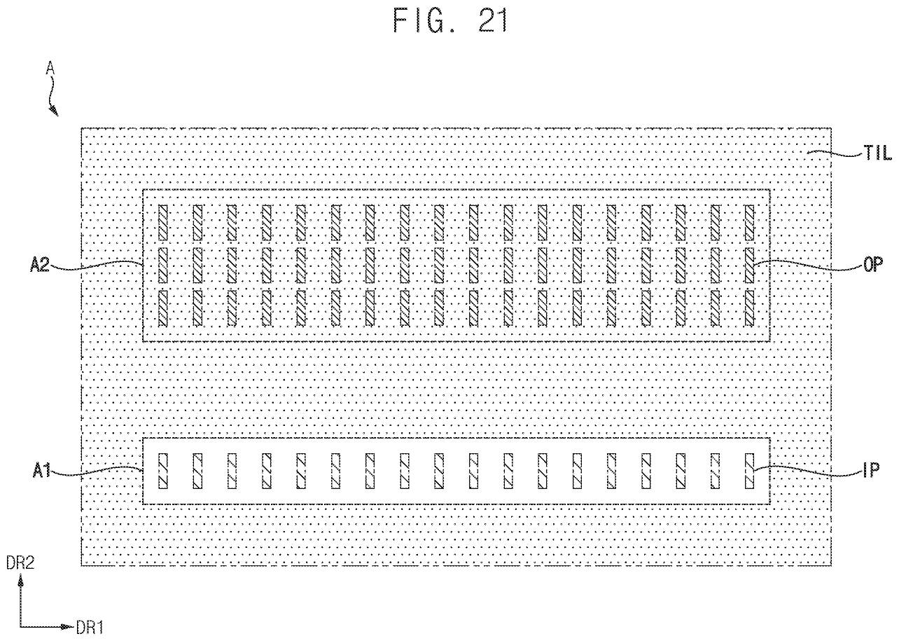

FIGS. 20 and 21 are enlarged plan views of other examples of area A of FIG. 1. Hereinafter, descriptions overlapping those described with reference to FIGS. and 5 will be omitted or simplified.

Referring to FIGS. 20 and 21, a plurality of pads may be located in the pad area PA on the substrate SUB. The plurality of pads may be repeatedly arranged along the first and second directions DR1 and DR2. The plurality of pads may include the plurality of input pads IP and the plurality of output pads OP.

The pad area PA may include the first area A1 and the second area A2. The plurality of input pads IP may be located in the first area A1, and the plurality of output pads OP may be located in the second area A2. For example, each of the first area A1 and the second area A2 may extend in the first direction DR1, and may be spaced apart from each other along the second direction DR2.

In one or more embodiments, as illustrated in FIG. 20, the touch insulating layer TIL may be located on the first area A1, and the touch insulating layer TIL may be omitted from the second area A2. That is, the first area A1 may be an area from which the touch insulating layer TIL is not removed, and the second area A2 may be an area from which the touch insulating layer TIL is removed. In this case, the touch insulating layer TIL may be entirely located in the remaining areas of the pad area PA other than the second area A2. The touch insulating layer TIL may correspond to the first and second touch insulating layers TIL1 and TIL2 illustrated in FIG. 7.

In one or more other embodiments, as illustrated in FIG. 21, the touch insulating layer TIL may be omitted from the first area A1, and the touch insulating layer TIL may be located in the second area A2. That is, the first area A1 may be an area from which the touch insulating layer TIL is removed, and the second area A2 may be an area from which the touch insulating layer TIL is not removed. In this case, the touch insulating layer TIL may be entirely located in the remaining areas of the pad area PA other than for the first area A1. The touch insulating layer TIL may correspond to the first and second touch insulating layers TIL1 and TIL2 illustrated in FIG. 7.

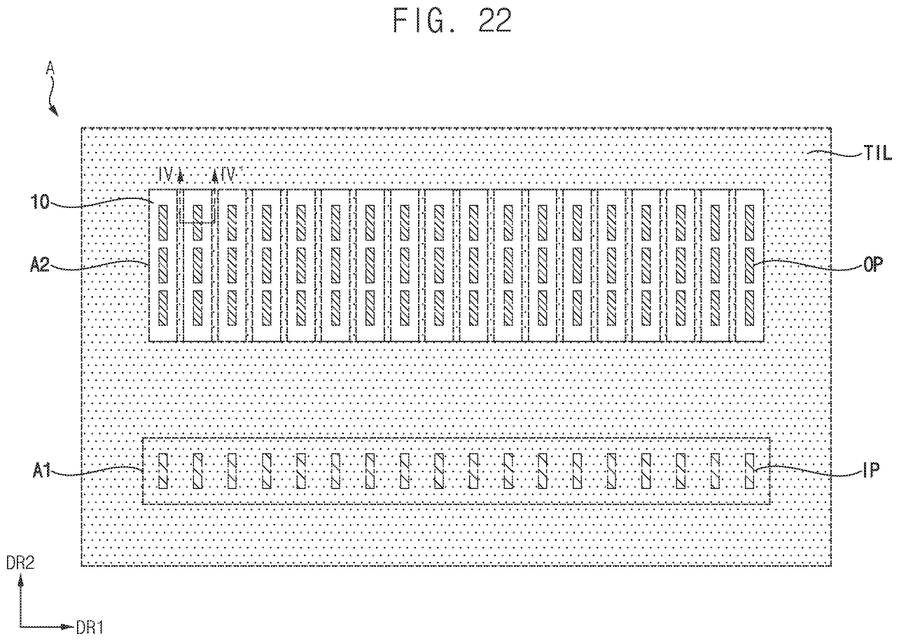

FIG. 22 is an enlarged plan view of another example of area A of FIG. 1. Hereinafter, descriptions overlapping those described with reference to FIGS. 4 and 5 will be omitted or simplified.

Referring to FIG. 22, a plurality of pads may be located in the pad area PA on the substrate SUB. The plurality of pads may be repeatedly arranged along the first and second directions DR1 and DR2. The plurality of pads may include the plurality of input pads IP and the plurality of output pads OP.

The pad area PA may include the first area A1 and the second area A2. The plurality of input pads IP may be located in the first area A1, and the plurality of output pads OP may be located in the second area A2. For example, each of the first area A1 and the second area A2 may extend in the first direction DR1, and may be spaced apart from each other along the second direction DR2.

In one or more embodiments, the second area A2 may include a plurality of first sub-areas 10 spaced apart from each other. The plurality of first sub-areas 10 may be spaced apart from each other along the first direction DR1, and each may extend in the second direction DR2. The touch insulating layer TIL may be omitted from each of the plurality of first sub-areas 10. That is, each of the plurality of first sub-areas 10 may be an area from which the touch insulating layer TIL is removed. In this case, the touch insulating layer TIL may be entirely located in the remaining areas of the pad area PA other than the plurality of first sub-areas 10. The touch insulating layer TIL may correspond to the first and second touch insulating layers TIL1 and TIL2 illustrated in FIG. 7.

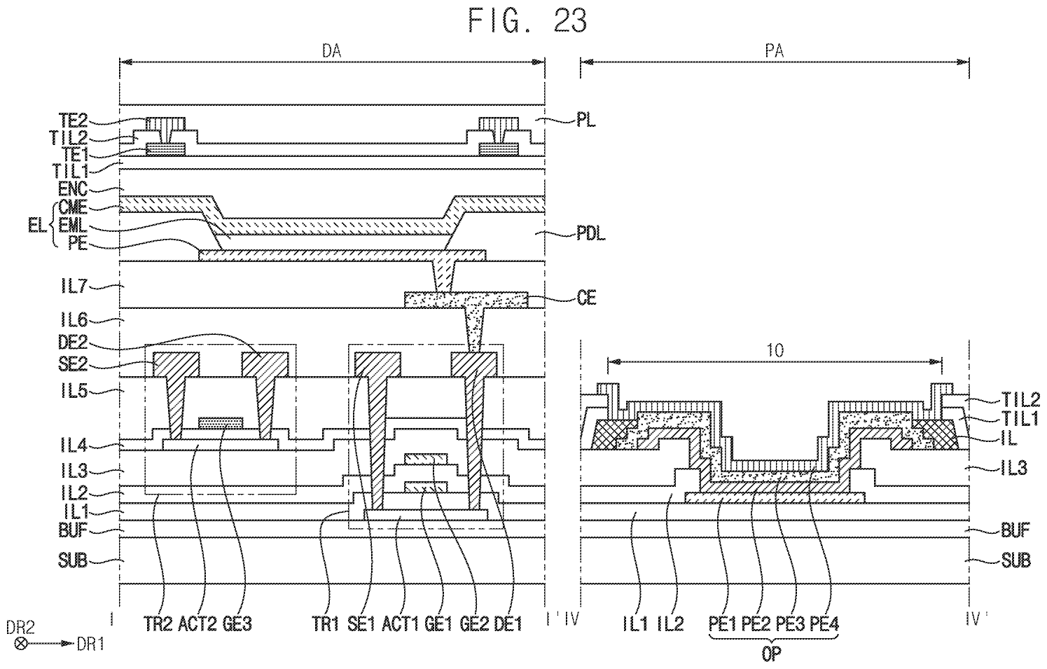

FIG. 23 is a cross-sectional view taken along the line I-I′ of FIG. 1 and the line IV-IV′ of FIG. 22.

Referring to FIGS. 22 and 23, the display device DD may include the substrate SUB, the buffer layer BUF, the first transistor TR1, the second transistor TR2, the first, second, third, fourth, fifth, sixth, and seventh insulating layers IL1, IL2, IL3, IL4, IL5, IL6, and IL7, the connection electrode CE, the output pad OP, the additional insulating layer IL, the pixel-defining layer PDL, the light-emitting element EL, the encapsulation layer ENC, the first touch insulating layer TIL1, the second touch insulating layer TIL2, the first touch electrodes TE1, the second touch electrodes TE2, and the protective layer PL. Hereinafter, descriptions overlapping those described with reference to FIG. 7 will be omitted or simplified.

The first touch insulating layer TIL1 may be located on the encapsulation layer ENC, and the second touch insulating layer TIL2 may be located on the first touch insulating layer TIL1. As described above, the first and second touch insulating layers TIL1 and TIL2 may be located in the remaining area of the pad area PA other than the first sub area 10. The first sub-area 10 may be an area in which the output pad OP is located.

In one or more embodiments, in the pad area PA, the first and second touch insulating layers TIL1 and TIL2 may cover side surfaces of the additional insulating layer IL, and may by omitted from the third pad electrode PE3 and the fourth pad electrode PE4. In addition, the first and second touch insulating layers TIL1 and TIL2 may not contact the third pad electrode PE3.

However, although the stacked structure of the output pad OP is illustrated in FIG. 23, the stacked structure of the input pad IP may also be substantially the same as the stacked structure of the output pad OP.

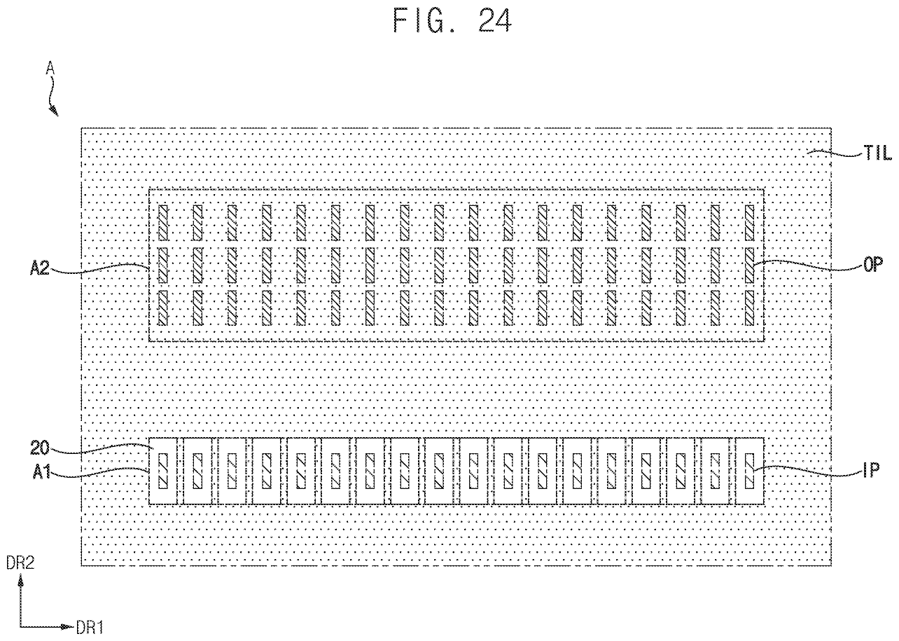

FIG. 24 is an enlarged plan view of another example of area A of FIG. 1. Hereinafter, descriptions overlapping those described with reference to FIGS. 4 and 5 will be omitted or simplified.

Referring to FIG. 24, a plurality of pads may be located in the pad area PA on the substrate SUB. The plurality of pads may be repeatedly arranged along the first and second directions DR1 and DR2. The plurality of pads may include the plurality of input pads IP and the plurality of output pads OP.

The pad area PA may include the first area A1 and the second area A2. The plurality of input pads IP may be located in the first area A1, and the plurality of output pads OP may be located in the second area A2. For example, each of the first area A1 and the second area A2 may extend in the first direction DR1 and may be spaced apart from each other along the second direction DR2.

In one or more embodiments, the first area A1 may include a plurality of second sub-areas 20 spaced apart from each other. The plurality of second sub-areas may be spaced apart from each other along the first direction DR1, and each may extend in the second direction DR2. The touch insulating layer TIL may be omitted from each of the plurality of second sub-areas 20. That is, each of the plurality of second sub-areas 20 may be an area from which the touch insulating layer TIL is removed. In this case, the touch insulating layer TIL may be entirely located in the remaining areas of the pad area PA other than the plurality of second sub-areas 20. The touch insulating layer TIL may correspond to the first and second touch insulating layers TIL1 and TIL2 illustrated in FIG. 7.

FIGS. 22 and 24 show that the input pads IP and the output pads OP are positioned inside the plurality of sub-areas 10 and 20, but as illustrated in FIG. 23, a portion of the output pads OP (or a portion of the input pads IP) may be exposed to the outside of the plurality of sub-areas 10 and 20.

However, the configuration of the present disclosure is not limited thereto. For example, unlike those illustrated in FIGS. 22 and 24, each of the first area A1 and the second area A2 may include the plurality of sub-areas 10 and 20 spaced apart from each other without the touch insulating layer TIL located therein.

The present disclosure can be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A display device comprising:
a substrate comprising a display area, and a pad area adjacent to the display area;
a transistor comprising:
an active pattern in the display area above the substrate;
a gate electrode above the active pattern; and
a source electrode and a drain electrode coupled to the active pattern;
a connection electrode above the transistor, and coupled to the transistor;
a touch layer above the connection electrode, and comprising an upper touch electrode;
pads above the substrate in the pad area, and comprising:
a first pad electrode comprising a same material as the gate electrode;
a second pad electrode above the first pad electrode, and comprising a same material as the source electrode and the drain electrode;
a third pad electrode above the second pad electrode, and comprising a same material as the connection electrode; and
a fourth pad electrode above the third pad electrode, and comprising a same material as the upper touch electrode; and
an additional insulating layer above the substrate in the pad area, covering an edge of the third pad electrode, and having an upper surface directly contacting the fourth pad electrode.

2. The display device of claim 1, wherein an entirety of a lower surface of the fourth pad electrode directly contacts the additional insulating layer or the third pad electrode.

3. The display device of claim 1, further comprising:
a first insulating layer above the active pattern, and covering the gate electrode and an edge of the first pad electrode; and
a second insulating layer above the first insulating layer, and covering an edge of the first insulating layer,
wherein the first and second insulating layers expose a central portion of the first pad electrode in the pad area.

4. The display device of claim 3, wherein the second pad electrode directly contacts the central portion of the first pad electrode.

5. The display device of claim 3, wherein openings are respectively defined in the additional insulating layer between adjacent ones of the pads, and expose an upper surface of the second insulating layer.

6. The display device of claim 5, wherein the pads are repeatedly arranged along a first direction and a second direction, which crosses the first direction, and
wherein first openings among the openings are respectively positioned between ones of the pads arranged along the first direction, and extend in the second direction.

7. The display device of claim 6, wherein second openings of the openings are respectively positioned between ones of the pads respectively arranged in a first row and in a second row, which is adjacent to the first row, and extend in the first direction.

8. The display device of claim 1, wherein the additional insulating layer comprises an organic material.

9. The display device of claim 1, further comprising:
a first organic insulating layer covering the source electrode and the drain electrode; and
a second organic insulating layer above the first organic insulating layer, and covering the connection electrode,
wherein the additional insulating layer comprises a same material as the second organic insulating layer.

10. The display device of claim 1, wherein the touch layer further comprises a touch insulating layer between the connection electrode and the upper touch electrode.

11. The display device of claim 10, wherein the pad area comprises a first area and a second area in which the pads are located, and wherein the touch insulating layer is omitted from the first area or the second area.

12. The display device of claim 11, wherein the first area or the second area comprises sub-areas spaced apart from each other along a first direction, and extending in a second direction crossing the first direction, and
wherein the touch insulating layer is omitted from the sub-areas.

13. The display device of claim 12, wherein the touch insulating layer covers a side surface of the additional insulating layer, and is omitted from between the third pad electrode and the fourth pad electrode.

14. The display device of claim 12, wherein the touch insulating layer is separated from the third pad electrode.

15. The display device of claim 1, wherein the third pad electrode comprises a first conductive layer, a second conductive layer, and a third conductive layer sequentially stacked, the first and third conductive layers protruding more than the second conductive layer in a direction toward the additional insulating layer.

16. The display device of claim 1, wherein the third pad electrode directly contacts the second pad electrode, and
wherein the fourth pad electrode directly contacts the third pad electrode.

17. A method for manufacturing a display device, the method comprising:
forming an active pattern in a display area above a substrate comprising the display area and a pad area, which is adjacent to the display area;
concurrently forming a gate electrode in the display area above the active pattern, and a first pad electrode in the pad area above the substrate;
concurrently forming a source electrode and a drain electrode coupled to the active pattern, and a second pad electrode above the first pad electrode;
concurrently forming a connection electrode coupled to the drain electrode, and a third pad electrode above the second pad electrode;
forming an additional insulating layer covering an edge of the third pad electrode;
forming a touch insulating layer above the connection electrode, the additional insulating layer, and the third pad electrode;
exposing a portion of an upper surface of the third pad electrode by removing a portion of the touch insulating layer in an area in which the first pad electrode, the second pad electrode, and the third pad electrode are positioned in the pad area; and
concurrently forming an upper touch electrode above the touch insulating layer, and a fourth pad electrode above the third pad electrode.

18. The method of claim 17, wherein the additional insulating layer covers the edge of the third pad electrode, and has an upper surface directly contacting the fourth pad electrode.

19. The method of claim 17, wherein an entirety of a lower surface of the fourth pad electrode directly contacts the additional insulating layer or the third pad electrode.

20. The method of claim 17, wherein the touch insulating layer covers a side surface of the additional insulating layer, is omitted from between the third pad electrode and the fourth pad electrode, and is separated from the third pad electrode.
